(19) United States
(12) Patent Application Publication
(10) Pub. No.: US 2024/0332902 A1
(43) Pub. Date: Oct. 3, 2024

(54) SURFACE EMITTING LASER, LASER DEVICE, DETECTION DEVICE, MOBILE OBJECT, AND SURFACE EMITTING LASER DRIVING METHOD

(71) Applicants: Kazuhiro HARASAKA, Miyagi (JP); Naoto JIKUTANI, Miyagi (JP)

(72) Inventors: Kazuhiro HARASAKA, Miyagi (JP); Naoto JIKUTANI, Miyagi (JP)

(21) Appl. No.: 18/577,709

(22) PCT Filed: Jun. 10, 2022
(86) PCT No.: PCT/IB2022/055393

§ 371 Date: Jan. 9, 2024

(30) Foreign Application Priority Data
Jul. 30, 2021 (JP) 2021-126011
Jan. 27, 2022 (JP) 2022-010790
Feb. 18, 2022 (JP) 2022-024125

(51) Int. Cl. H01S 5/183; H01S 5/00; H01S 5/042; H01S 5/062

(52) U.S. Cl. CPC H01S 5/18311; H01S 5/0014; H01S 5/04256; H01S 5/06216; H01S 5/18327

(57) ABSTRACT

A surface emitting includes: an active layer; multiple reflectors facing each other with the active layer therebetween; and an electrode pair coupled to a power supply device and configured to inject current into the active layer. The surface emitting laser has: a current injection period in which the current is injected by the power supply device to oscillate no laser beam; and a current decrease period after the current injection period, in which a current value of the current injected into the active layer is lower than a current value of the current injected during the current injection period, to oscillate a laser beam.

### TECHNICAL FIELD

The present disclosure relates to a surface emitting laser, a laser device, a detection device, a mobile object, and a surface emitting laser driving method.

### BACKGROUND ART

The safety standards for lasers against human eyes are classified in accordance with the classes of eye-safe, and are determined in IEC 60825-1 Ed. 3 (corresponding to Japanese Industrial Standard (JIS) C 6802). To use a distance measurement device in various environments, it is desirable to satisfy the standards of Class 1 in which a safety measure or a warning is not required. The upper limit of the average power is determined as one of the standards of Class 1. In the case of pulsed light, the peak output, the pulse width, and the duty ratio of the pulsed light are converted into the average power and the average power is compared with standard values. Since the allowable peak output increases as the pulse width of the optical pulse decreases, a laser beam source with a high peak output and a short pulse width is useful for both an increase in precision and an increase in distance in a time of flight (TOF) sensor while satisfying eye-safe.

Measures for reducing the width of a pulse to 1 ns or less include gain switching, Q-switching, and mode-locking. The gain switching is a measure for providing a pulse width of 100 ps or less by using a relaxation oscillation phenomenon. Merely controlling the pulse current can provide such a pulse width, and hence the configuration for the guide switching is simpler than that for the Q-switching or mode-locking.

However, since the gain switching uses the relaxation oscillation phenomenon, multiple pulse trains are likely to be output after the leading pulse. In another situation, tail light (tailing) with a wide pulse width is likely to be output after the relaxation oscillation has subsided. These phenomena are not desirable for application. For example, when a single photon avalanche diode (SPAD) is used to perform detection of the Geiger mode, the highest peak output is the target of sensing, and multiple pulses other than the target pulse result in noise. Moreover, tail light is unnecessary energy, which is disadvantageous in terms of eye-safe.

### CITATION LIST

### Patent Literature

### [PTL 1]

U.S. Pat. No. 8,934,514-B

### SUMMARY OF INVENTION

### Technical Problem

There is room for study on a surface emitting laser capable of generating short-pulse light with reduced tailing.

An object of the present disclosure is to provide a surface emitting laser, a laser device, a detection device, a mobile object, and a surface emitting laser driving method capable of obtaining short-pulse light with reduced tailing.

### Solution to Problem

According to an aspect of the disclosed technology, a surface emitting laser includes: an active layer; multiple reflectors facing each other with the active layer therebetween; and an electrode pair coupled to a power supply device and configured to inject current into the active layer. The surface emitting laser has: a current injection period in which the current is injected by the power supply device to oscillate no laser beam; and a current decrease period after the current injection period, in which a current value of the current injected into the active layer is lower than a current value of the current injected during the current injection period, to oscillate a laser beam.

According to another aspect of the disclosed technology, a surface emitting laser is configured to, when a time width of 1/e² of a peak value is defined as an optical pulse width, emit a single optical pulse having an optical pulse width of 110 ps or less.

According to still another aspect of the disclosed technology, a detection device includes: the above-described laser device; and a detector configured to detect light emitted from the surface emitting laser and reflected by an object.

According to yet another aspect of the disclosed technology, a detection device includes the above-described laser device; and a detector configured to detect light emitted from the surface emitting laser and reflected by an object.

Further, a mobile object includes the above-described detection device.

Still further, a surface emitting laser driving method, performed by a surface emitting laser including an active layer, multiple reflectors facing each other with the active layer therebetween, and an electrode pair coupled to a power supply and configured to inject current into the active layer, includes: oscillating no laser beam during a current injection period in which the current is injected by a power supply device; and oscillating a laser beam during a current decrease period after the current injection period, in which a current value of the current injected into the active layer is lower than a current value of the current injected during the current injection period.

### Advantageous Effects of Invention

With the disclosed technology, short-pulse light with reduced tailing can be obtained.

### BRIEF DESCRIPTION OF DRAWINGS

The accompanying drawings are intended to depict example embodiments of the present invention and should not be interpreted to limit the scope thereof. The accompanying drawings are not to be considered as drawn to scale unless explicitly noted. Also, identical or similar reference numerals designate identical or similar components throughout the several views.

FIG. 1 is a cross-sectional view illustrating a surface emitting laser according to a first embodiment.

FIG. 2 is a cross-sectional view illustrating an oxidized confinement layer and the vicinity thereof according to the first embodiment.

FIG. 3 is a cross-sectional view illustrating an oxidized confinement layer and the vicinity thereof according to a comparative example.

FIG. 4 is an equivalent circuit diagram illustrating a circuit used for actual measurement.

FIG. 5A is a graph presenting an actual measurement result of the comparative example.

FIG. 5B is a graph presenting an actual measurement result of the comparative example.

FIG. 5C is a graph presenting an actual measurement result of the comparative example.

FIG. 6A is a graph presenting an actual measurement result of the first embodiment.

FIG. 6B is a graph presenting an actual measurement result of the first embodiment.

FIG. 6C is a graph presenting an actual measurement result of the first embodiment.

FIG. 7A is a graph presenting a difference in distributions of electric field intensity and equivalent refractive index depending on a structure, according to the comparative example.

FIG. 7B is a graph presenting a difference in distributions of electric field intensity and equivalent refractive index depending on a structure, according to an embodiment.

FIG. 8A is a graph presenting a change in distributions of electric field intensity and equivalent refractive index over time.

FIG. 8B is a graph presenting a change in distributions of electric field intensity and equivalent refractive index over time.

FIG. 9 is a graph presenting simulation results for carrier density and threshold carrier density according to the reference example.

FIG. 10 is a graph presenting simulation results for optical output according to the reference example.

FIG. 11 is a graph presenting an example of a function used in a simulation according to the first embodiment.

FIG. 12 is a graph presenting simulation results for optical output according to the first embodiment.

FIG. 13A is a graph presenting simulation results for carrier density, threshold carrier density, and photon density according to the first embodiment.

FIG. 13B is a graph presenting a simulation result for optical confinement factor in a lateral direction according to the first embodiment.

FIG. 14A is a partially enlarged graph of FIG. 13A.

FIG. 14B is a partially enlarged graph of FIG. 13B.

FIG. 15A is a graph presenting an example of an actual measurement result of optical pulses.

FIG. 15B is a graph presenting an example of a simulation result of optical pulses.

FIG. 16 is a cross-sectional view illustrating a first model used for a simulation.

FIG. 17A illustrates a cross-sectional profile of an electric field intensity distribution of a fundamental mode.

FIG. 17B illustrates a cross-sectional profile of an electric field intensity distribution of the fundamental mode.

FIG. 18 is a graph presenting calculation results of the relationship among the optical confinement factor, the thickness of an oxidized confinement layer, and the diameter of a non-oxidized region.

FIG. 19 is a graph presenting calculation results of the relationship between the thickness of an oxidized confinement layer and the optical confinement factor for the first model;

FIG. 20 is a cross-sectional view illustrating a second model used for a simulation.

FIG. 21 is a cross-sectional view illustrating a third model used for a simulation, according to the comparative example.

FIG. 22 is a graph presenting calculation results of the relationship between the amount of decrease in refractive index and the optical confinement factor for the second model and the third model.

FIG. 23A is a cross-sectional view of a fourth model used for a simulation.

FIG. 23B is an enlarged view of a portion of FIG. 23A.

FIG. 24 is a graph presenting calculation results of the relationship between the thickness of an oxidized region at a position 3 μm separated outward from the boundary and the optical confinement factor for the fourth model.

FIG. 25 is a graph presenting the relationship between the current confinement area and the peak optical output.

FIG. 26 is a cross-sectional view illustrating a surface emitting laser according to a second embodiment.

FIG. 27 is a diagram illustrating a laser device according to a third embodiment.

FIG. 28 is a graph presenting the relationship between the duty ratio and the peak output of optical pulses.

FIG. 29 is a diagram illustrating a distance measurement device according to a fourth embodiment.

FIG. 30 is a diagram illustrating a mobile object according to a fifth embodiment.

### DESCRIPTION OF EMBODIMENTS

The terminology used herein is for the purpose of describing particular embodiments only and is not intended to be limiting of the present invention. As used herein, the singular forms “a”, “an” and “the” are intended to include the plural forms as well, unless the context clearly indicates otherwise.

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Embodiments of the present disclosure are described below with reference to the accompanying drawings. In the specification and the drawings, components having substantially the same functional configuration are denoted by the same reference sign, and redundant description may be omitted.

### First Embodiment

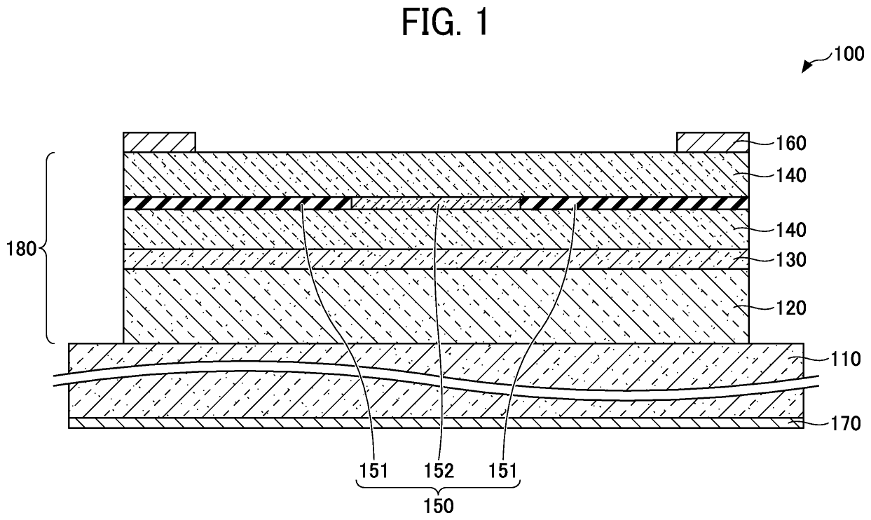

A first embodiment is described first. The first embodiment relates to a surface emitting laser. FIG. 1 is a cross-sectional view illustrating a surface emitting laser 100 according to the first embodiment.

The surface emitting laser 100 according to the first embodiment is, for example, a vertical cavity surface emitting laser (VCSEL) using oxidation confinement. The surface emitting laser 100 includes an n-type GaAs substrate 110, an n-type distributed Bragg reflector (DBR) 120, an active layer 130, a p-type DBR 140, an oxidized confinement layer 150, an upper electrode 160, and a lower electrode 170.

In the present embodiment, light is emitted in a direction perpendicular to a surface of the n-type GaAs substrate 110. Hereinafter, the direction perpendicular to the surface of the n-type GaAs substrate 110 may be referred to as a vertical direction, and the direction parallel to the surface of the n-type GaAs substrate 110 may be referred to as a lateral direction or an in-plane direction.

The n-type DBR 120 is on the n-type GaAs substrate 110. The n-type DBR 120 is, for example, a semiconductor multilayer-film reflecting mirror including multiple n-type semiconductor films stacked on one another. The active layer 130 is on the n-type DBR 120. The active layer 130 includes, for example, multiple quantum well layers and multiple barrier layers. The active layer 130 is included in a resonator. The p-type DBR 140 is on the active layer 130. The p-type DBR 140 is, for example, a semiconductor multilayer-film reflecting mirror including multiple p-type semiconductor films stacked on one another. In the resonator, the active layer 130 is provided at a position on the antinode side with respect to the middle between the antinode and the node of a standing wave of oscillated light. When the active layer 130 is provided at a position corresponding to the antinode of a standing wave, emission efficiency is the highest.

The upper electrode 160 is in contact with an upper surface of the p-type DBR 140. The lower electrode 170 is in contact with a lower surface of the n-type GaAs substrate 110. The pair of the upper electrode 160 and the lower electrode 170 is an example of an electrode pair. However, the positions of the electrodes are not limited thereto, and may be any positions as far as the electrodes can inject current into the active layer. For example, an intracavity structure may be employed in which electrodes are directly disposed in a spacer layer of a resonator instead of via a DBR.

The p-type DBR 140 includes, for example, the oxidized confinement layer 150. The oxidized confinement layer 150 contains Al. The oxidized confinement layer 150 includes an oxidized region 151 and a non-oxidized region 152 in a plane perpendicular to the direction in which light is emitted (hereinafter, referred to as an emission direction of light). The oxidized region 151 has an annular planar shape and surrounds the non-oxidized region 152. The non-oxidized region 152 includes a p-type AlAs layer 155 and two p-type Al_{0.85}Ga_{0.15}As layers 156 that sandwich the p-type AlAs layer 155 in the vertical direction. The oxidized region 151 is made of AlOₓ. The refractive index of the oxidized region 151 is lower than the refractive index of the non-oxidized region 152. For example, the refractive index of the oxidized region 151 is 1.65, the refractive index of the p-type AlAs layer 155 is 2.96, and the refractive index of the p-type Al_{0.85}Ga_{0.15}As layers 156 is 3.04. In plan view, a portion of a mesa 180 inside an inner edge of the oxidized region 151 is an example of a high refractive index region, and a portion of the mesa 180 outside the inner edge of the oxidized region 151 is an example of a low refractive index region. In one example, p-type AlₓGa₁₋ₓAs layers (0.70≤x≤0.90) may be provided instead of the p-type Al_{0.85}Ga_{0.15}As layers 156. In the present embodiment, the p-type DBR 140, the active layer 130, and the n-type DBR 120 constitute the mesa 180. However, in the present embodiment in which a current confinement region is formed by oxidation confinement, at least the oxidized confinement layer 150 and a semiconductor layer located above the oxidized confinement layer 150 are formed in a mesa shape. When at least the active layer is formed to be included in the mesa, light generated in the active layer can be prevented from leaking in the lateral direction.

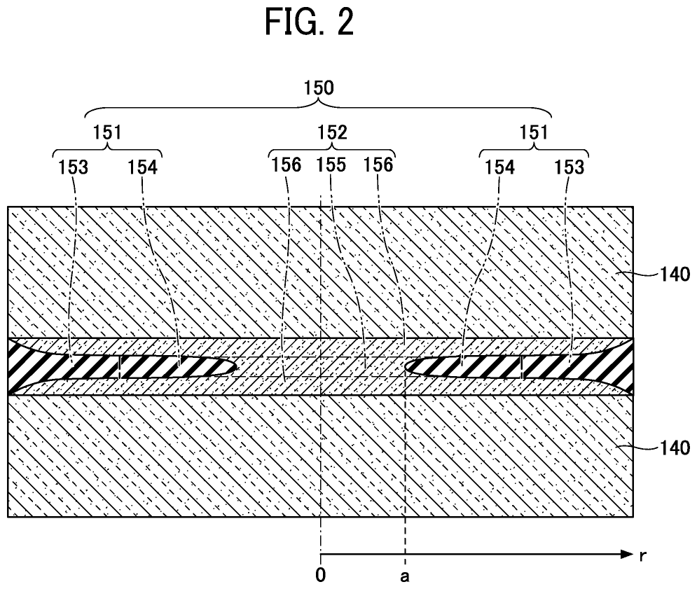

The oxidized confinement layer 150 is described in detail. FIG. 2 is a cross-sectional view illustrating the oxidized confinement layer 150 and the vicinity thereof according to the first embodiment.

As illustrated in FIG. 2, the oxidized region 151 has, in plan view, an annular outer region 153 and an annular inner region 154. The outer region 153 is exposed from a side surface of the mesa 180. The outer region 153 is a region in which the thickness changes so that the contact surface of the surface is located in an outer section of the oxidized region 151 in cross-sectional view. The inner region 154 is a region in which the thickness changes so that the contact surface of the surface is located in an inner section of the oxidized region 151 in cross-sectional view. The inner region 154 is located inside the outer region 153. The thickness of the inner region 154 matches the thickness of the outer region 153 at the boundary with the outer region 153, and decreases toward the center of the mesa 180. The inner region 154 has a tapered shape that is gradually thicker from the inner edge to the boundary with the outer region 153 in cross-sectional view. The non-oxidized region 152 is located inside the outer region 153. Portions of the non-oxidized region 152 sandwich the inner region 154 in the vertical direction. The other portion of the non-oxidized region 152 is located inside the inner edge of the inner region 154 in plan view. For example, the thickness of the non-oxidized region 152 is 35 nm or less. The thickness of the outer region 153 may be larger than the thickness of the non-oxidized region 152. In the embodiment of the present disclosure, the thickness of the non-oxidized region 152 is the thickness of a portion on the center side of the mesa 180 with respect to the inner edge of the oxidized region 151 (the inner edge of the inner region 154). For example, the distance from the side surface of the mesa 180 to the inner edge of the oxidized region 151 is in a range from about 8 μm to about 11 μm.

The oxidized region 151 is formed by, for example, oxidation confinement of a p-type AlAs layer and a p-type Al_{0.85}Ga_{0.15}As layer. For example, the oxidized region 151 can be formed by oxidizing the p-type AlAs layer and the p-type Al_{0.85}Ga_{0.15}As layer in a high-temperature water vapor environment. Even when the same p-type AlAs layer and the same p-type Al_{0.85}Ga_{0.15}As layer are oxidized, the structure of the oxidized confinement layer obtained from the p-type AlAs layer and the p-type Al_{0.85}Ga_{0.15}As layer may vary depending on the conditions of oxidation. Thus, even when the layers to be the oxidized confinement layer 150 by oxidation, for example, the p-type AlAs layer and the p-type Al_{0.85}Ga_{0.15}As layer have the same structures as those before oxidation, the oxidized confinement layer 150 including the oxidized region 151 and the non-oxidized region 152 is not obtained in some cases depending on the conditions of oxidation.

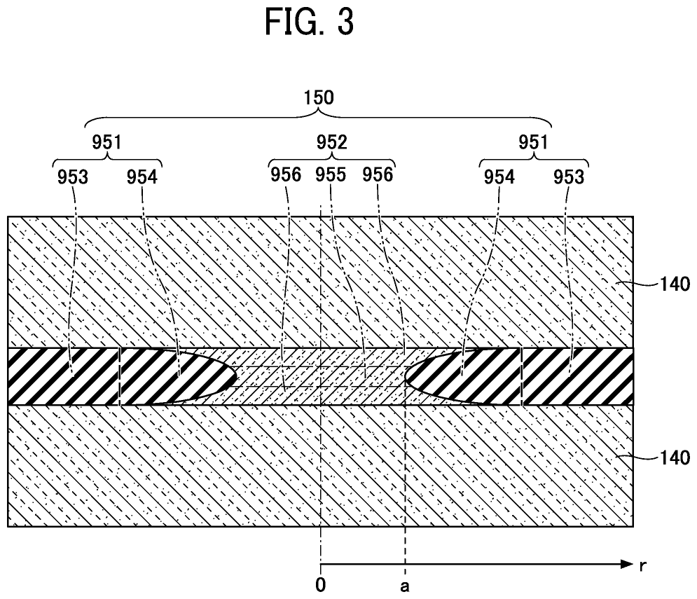

The advantageous effect of the first embodiment is described in comparison with a reference example. FIG. 3 is a cross-sectional view illustrating an oxidized confinement layer 150 and the vicinity thereof according to the reference example.

In the reference example, the oxidized confinement layer 150 includes an oxidized region 951 and a non-oxidized region 952 instead of the oxidized region 151 and the non-oxidized region 152. The oxidized region 951 has an annular planar shape and surrounds the non-oxidized region 952. The non-oxidized region 952 includes a p-type AlAs layer 955 and two p-type Al_{0.85}Ga_{0.15}As layers 956 that sandwich the p-type AlAs layer 955 in the vertical direction. The oxidized region 951 is made of AlOₓ. The oxidized region 951 has, in plan view, an annular outer region 953 and an annular inner region 954. The outer region 953 is exposed from a side surface of a mesa 180. The thickness of the outer region 953 is constant in the in-plane direction. The inner region 954 is located inside the outer region 953. The thickness of the inner region 954 matches the thickness of the outer region 953 at the boundary with the outer region 953, and decreases toward the center of the mesa 180. The inner region 954 has a tapered shape that is gradually thicker from an inner edge to the boundary with the outer region 953 in cross-sectional view. The non-oxidized region 952 is located inside the outer region 953. Portions of the non-oxidized region 952 sandwich the inner region 954 in the vertical direction. The other portion of the non-oxidized region 952 is located inside the inner edge of the inner region 954 in plan view. For example, the distance from the side surface of the mesa 180 to the inner edge of the oxidized region 951 is in a range from about 8 μm to about 11 μm. The thicknesses of the oxidized region 951 and the non-oxidized region 952 are equal to the thickness of the oxidized confinement layer 150.

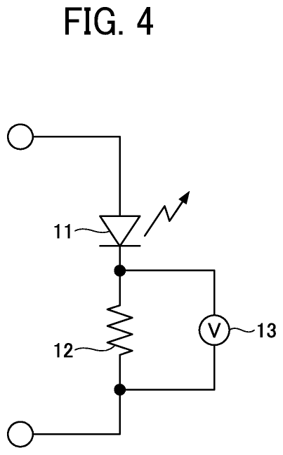

Actual measurement results according to the first embodiment and the reference example are described first. FIG. 4 is an equivalent circuit diagram illustrating a circuit used for actual measurement.

In this circuit, a resistor 12 for monitoring current is coupled in series to a surface emitting laser 11 corresponding to the first embodiment or the reference example. A voltmeter 13 is coupled in parallel to the resistor 12. Light output from the surface emitting laser 11 was received by a wide-band high-speed photodiode and converted into a voltage signal. The voltage signal was observed with an oscilloscope.

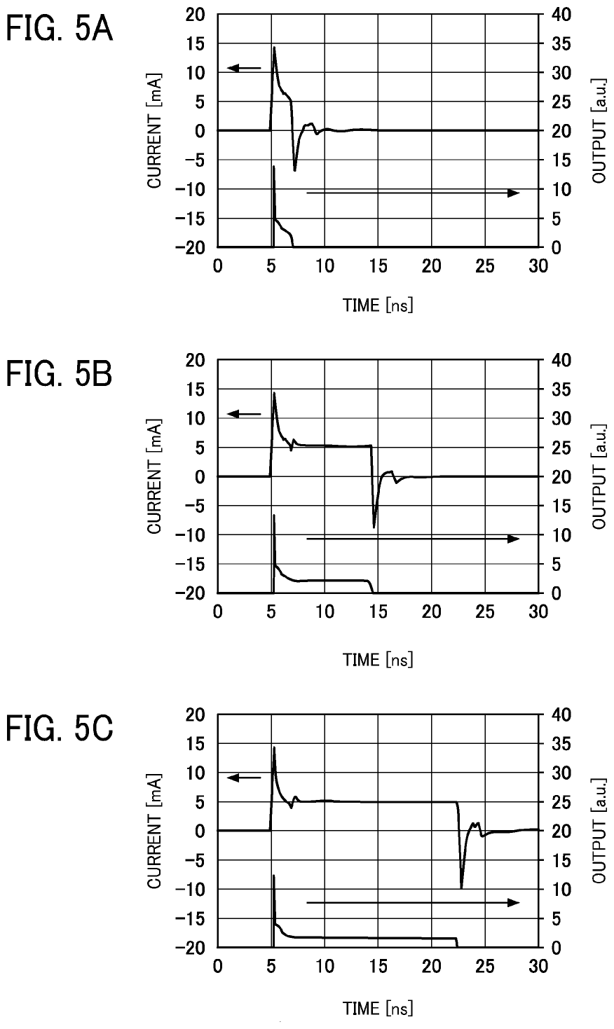

FIGS. 5A to 5C are graphs presenting actual measurement results of the reference example. FIG. 5A presents an actual measurement result when the width of pulse current is about 2 ns. FIG. 5B presents an actual measurement result when the width of pulse current is about 9 ns. FIG. 5C presents an actual measurement result when the width of pulse current is about 17 ns. In the actual measurement in FIGS. 5A to 5C, the magnitude of bias current and the amplitude of pulse current are common. FIGS. 5A to 5C each present current flowing through the resistor 12 and an optical output measured by the high-speed photodiode. The current flowing through the resistor 12 can be calculated using the voltmeter 13.

As presented in FIGS. 5A to 5C, in the reference example, regardless of the magnitude of the width of pulse current, an optical pulse is output immediately after the pulse current is injected, then an equilibrium state is established until the injection of the pulse current is stopped, and constant tail light is output. The leading optical pulse is caused by relaxation oscillation, which is typical driving by gain switching. Even when the pulse width is changed, the timing at which the optical pulse is generated does not change. This is because the optical pulse generated by the relaxation oscillation is generated immediately after the carrier density in the laser resonator exceeds the threshold carrier density. To reduce the output of tail light, the current injection may be stopped immediately after the optical pulse is output. However, since the time width of the optical pulse caused by the relaxation oscillation is 100 ps or less, when the magnitude of the current is as large as 10 A or more, it is difficult to stop the injection of the current in a period of 100 ps or less immediately after the optical pulse is output.

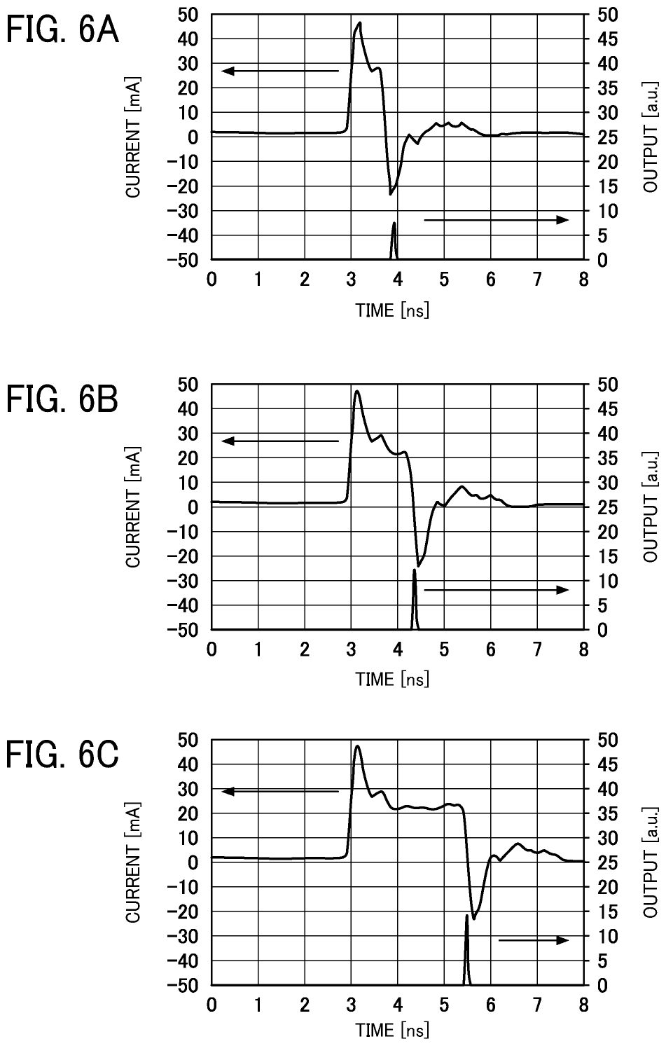

FIGS. 6A to 6C are graphs presenting actual measurement results of the first embodiment. FIG. 6A presents an actual measurement result when the width of pulse current is about 0.8 ns. FIG. 6B presents an actual measurement result when the width of pulse current is about 1.3 ns. FIG. 6C presents an actual measurement result when the width of pulse current is about 2.5 ns. In the actual measurement in FIGS. 6A to 6C, the magnitude of bias current and the amplitude of pulse current are common. FIGS. 6A to 6C each present current flowing through the resistor 12 and an optical output measured by the high-speed photodiode. The current flowing through the resistor 12 can be calculated using the voltmeter 13.

As presented in FIGS. 6A to 6C, in the first embodiment, an optical output is not generated in a state in which pulse current is injected, and an optical pulse is output immediately after the injection of the pulse current decreases. Moreover, tail light after the optical pulse is output is almost not observed. In the case of the optical output by gain switching, the timing at which the optical pulse is generated does not change even when the width of the pulse current is changed. In contrast, according to the first embodiment, the optical pulse is output when the injection of the pulse current decreases. Thus, the optical output according to the first embodiment is not based on normal gain switching using the relaxation oscillation phenomenon.

As described above, the first embodiment and the reference example clearly differ from each other in the mechanism and manner of the optical output. The difference is described as follows.

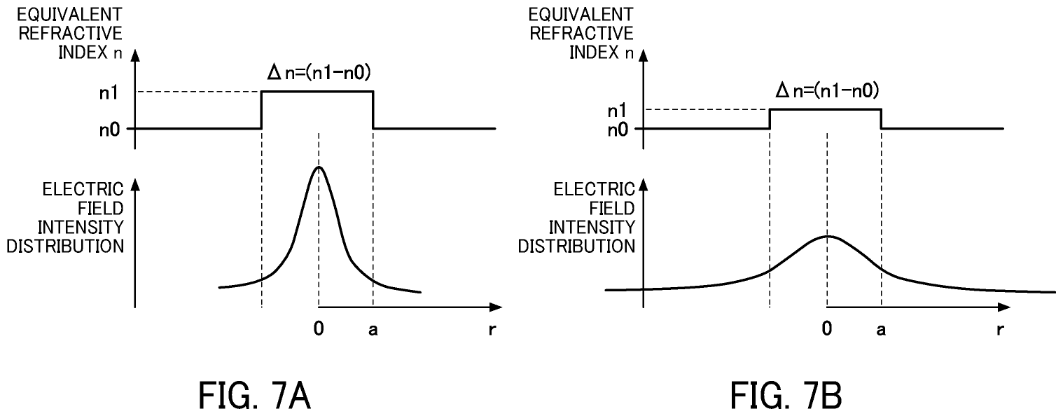

In a surface emitting laser, a laser beam propagates in a resonator in a direction perpendicular to an oxidized confinement layer. Thus, as the oxidized confinement layer is thicker, an equivalent waveguide length dependent on the difference in refractive index increases, and an optical confinement effect in the lateral direction increases. When a DBR including the oxidized confinement layer is considered as an equivalent waveguide structure, the electric field intensity distribution of laser beams is concentrated around the center when the difference in equivalent refractive index is large as presented in FIG. 7A. In contrast, when the difference in equivalent refractive index is small as presented in FIG. 7B, the electric field intensity distribution of laser beams expands to the oxidized region in the periphery. When the first embodiment is compared with the reference example, since the oxidized confinement layer 150 includes the inner region 154 in the first embodiment, the difference in equivalent refractive index decreases in the first embodiment. Thus, the electric field intensity distribution of the laser beams is concentrated around the center in the reference example as presented in FIG. 7A. In contrast, the electric field intensity distribution of the laser beams expands to the oxidized region 151 in the first embodiment as presented in FIG. 7B.

In this case, an optical confinement factor in the lateral direction is defined as a ratio of “an integrated intensity of an electric field in a region having the same radius as a current passing region” to “an integrated intensity of an electric field in a lateral cross-section passing through the center of a surface emitting laser element”, and is expressed by Equation (1). In this case, a corresponds to a radius of the current passing region, and Φ represents a rotation direction around a rotation axis in the direction perpendicular to the substrate.

### [Math. 1]

$$\\ \begin{matrix}{Γ}_{r} = \frac{{\int }_{0}^{a} {\int }_{0}^{2 π} {\vert E \vert}^{2} \cdot rd Φ dr}{{\int }_{0}^{∞} {\int }_{0}^{2 π} {\vert E \vert}^{2} \cdot rd Φ dr} & ( 1 )\end{matrix}$$

A model of a phenomenon that occurs when injection of pulse current is stopped is described next. In a state in which the pulse current is injected, the current path is concentrated around the center of the mesa by the oxidized confinement layer, and the carrier density is high. At this time, an effect of decreasing the refractive index is generated by a carrier plasma effect in the non-oxidized region having a high carrier density. The carrier plasma effect is a phenomenon in which the refractive index decreases in proportion to a free carrier density. Referring to, for example, Kobayashi, Soichi, et al., “Direct Frequency Modulation in AlGaAs Semiconductor Lasers”, IEEE Transactions on Microwave Theory and Techniques, Volume 30, Issue 4, 1982, pp. 428-441, the amount of change in refractive index is expressed by Equation (2). In this case, N is a carrier density.

[Math. 2]

Δn≈−4×10⁻²¹[cm³]×N[1/cm³] (2)

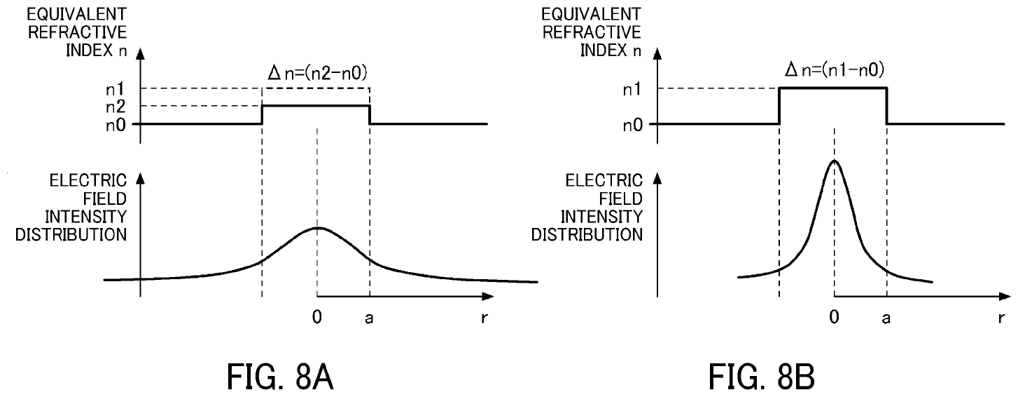

FIG. 8A schematically presents an equivalent refractive index and an electric field intensity distribution in a period in which pulse current is injected. FIG. 8B schematically presents an equivalent refractive index and an electric field intensity distribution in a period in which the injection of the pulse current is stopped and the pulse current decreases. The carrier plasma effect acts in a direction to cancel out the equivalent refractive-index difference (n1−n0) generated by the oxidized confinement layer in the period in which the pulse current is injected, and hence the equivalent refractive-index difference is (n2−n0). When the injection of the pulse current decreases in this state, the carrier plasma effect no longer acts, and the equivalent refractive-index difference returns to (n1−n0). Thus, photons that have spread to the peripheral portion of the mesa are concentrated in the center portion of the mesa, and the photon density in the non-oxidized region increases. That is, the state changes to a state in which lateral optical confinement is strong. When the injection of the pulse current is stopped, carriers accumulated in the resonator decrease over the carrier lifetime. However, when the lateral optical confinement increases before the carrier density completely attenuates, induced emission starts, the accumulated carriers are consumed at once, and an optical pulse is output. The period in which the pulse current is injected is an example of a current injection period, and the period in which the injection of the pulse current is stopped and the pulse current decreases is an example of a current decrease period.

The results of verification of the above-described model through a simulation are described below. The rate equations of the carrier density and the photon density are expressed in Equations (3) and (4).

### [Math. 3]

$$\\ \begin{matrix}\frac{dN}{dt} = \frac{i ( t )}{eV} - \frac{N}{{τ}_{n} ( N )} - {v}_{g} g ( N , S ) S & ( 3 )\end{matrix}$$

### [Math. 4]

$$\\ \begin{matrix}\frac{dS}{dt} = ( {Γ}_{a} {v}_{g} g ( N , S ) - \frac{1}{{τ}_{p}} ) {}_{} S + \frac{{Γ}_{a} β N}{{τ}_{n} ( N )} & ( 4 )\end{matrix}$$

The content indicated by each character in Equations (3) and (4) is as follows. N denotes a carrier density [1/cm³], S denotes a photon density [1/cm³], i(t) denotes injection current [A], e denotes an elementary charge [C], V denotes a resonator volume [cm³], trn(N) denotes a carrier lifetime [s], v_{g} denotes a group velocity [cm/s], g(N, S) denotes a gain [1/cm], Γₐ denotes an optical confinement factor, τₚ denotes a photon lifetime [s], β denotes a spontaneous emission coupling factor, go denotes a gain factor [1/cm], ε denotes a gain suppression factor, Nₜᵣ denotes a transparency carrier density [1/cm³], ηᵢ denotes a current injection efficiency, αₘ denotes a resonator mirror loss [1/cm], h denotes the Planck constant [Js], and ν denotes a frequency of light [1/s].

The gain g(N, S) is expressed by Equation (5).

### [Math. 5]

$$\\ \begin{matrix}g ( N , S ) = \frac{{g}_{0}}{1 + ε S} ln \frac{N}{{N}_{tr}} & ( 5 )\end{matrix}$$

As expressed in Equation (6), the optical confinement factor Γₐ is defined by the product of an optical confinement factor Γᵣ in the lateral direction and an optical confinement factor Γ_{z} in the vertical direction.

[Math. 6]

Γₐ=Γᵣ×Γ_{z} (6)

A threshold carrier density Nₜₕ is expressed by Equation (7).

### [Math. 7]

$$\\ \begin{matrix}{N}_{th} = {N}_{tr} \cdot exp ( \frac{1}{{Γ}_{a} \cdot {g}_{0} \cdot {v}_{g} \cdot {τ}_{p}} ) & ( 7 )\end{matrix}$$

A threshold current Iₜh and the threshold carrier density Nₜₕ have a relationship expressed by Equation (8).

### [Math. 8]

$$\\ \begin{matrix}\frac{{η}_{i} \cdot {I}_{th}}{e \cdot V} = \frac{{N}_{th}}{{τ}_{n} ( N )} & ( 8 )\end{matrix}$$

An optical output P that is output from the resonator and the photon density S have a relationship expressed by Equation (9).

### [Math. 9]

$$\\ \begin{matrix}P = {v}_{g} \cdot {α}_{m} \cdot S \cdot hv \cdot \frac{V}{{Γ}_{a}} & ( 9 )\end{matrix}$$

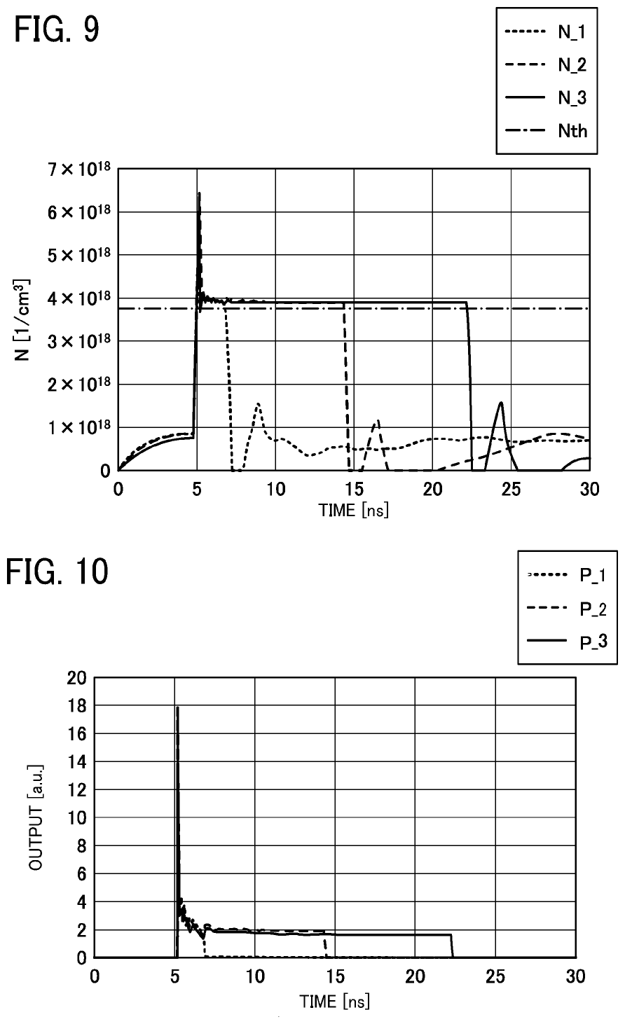

Simulation results according to the reference example are described. For the reference example, a simulation was performed with inputs of the current monitor waveforms presented in FIGS. 5A to 5C while the optical confinement factor Γᵣ in the lateral direction was 1. FIG. 9 presents simulation results for the carrier density N and the threshold carrier density Nₜₕ. FIG. 10 presents simulation results for the optical outputs.

As presented in FIGS. 9 and 10, at the time point of about 5 ns at which the pulse current is injected, the carrier density N exceeds the threshold carrier density Nₜₕ immediately thereafter, and an optical pulse caused by the relaxation oscillation is output. Then, an equilibrium state is established and constant tail light is output. As described above, in the simulation, results close to the actual measurement results presented in FIGS. 5A to 5C are obtained.

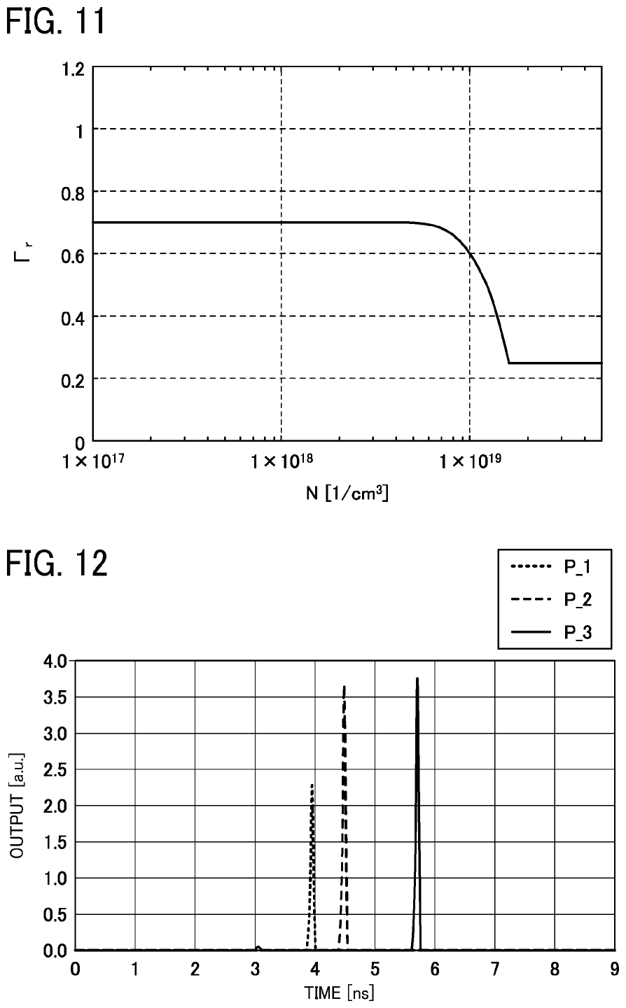

Results of the simulation according to the first embodiment are described next. For the first embodiment, a simulation was performed with inputs of the current monitor waveforms presented in FIGS. 6A to 6C while the optical confinement factor Γᵣ in the lateral direction was less than 1 and the optical confinement factor Γᵣ in the lateral direction was a function that decreases as the carrier density N increases. The reason why the optical confinement factor Γᵣ in the lateral direction is the above-described function is to take in the influence of a change in refractive index due to the carrier plasma effect. FIG. 11 is a graph presenting an example of the function. FIG. 12 is a graph presenting simulation results for the optical outputs.

As presented in FIG. 12, an optical pulse output is obtained at a timing at which the injection of the pulse current is stopped. As described above, in the simulation, results close to the actual measurement results presented in FIGS. 6A to 6C are obtained.

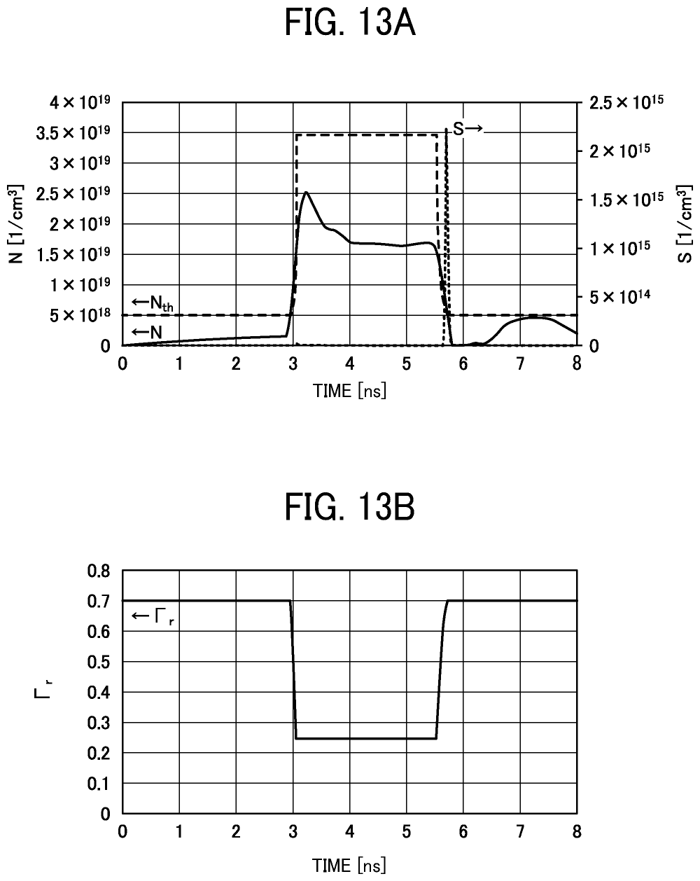

To analyze the results in detail, FIGS. 13A and 13B present simulation results of the carrier density N, the threshold carrier density Nₜₕ, the photon density S, and the optical confinement factor Γᵣ in the lateral direction under the condition of the pulse width being 2.5 ns. FIG. 13A presents simulation results of the carrier density N, the threshold carrier density Nₜₕ, and the photon density S. FIG. 13B presents a simulation result of the optical confinement factor Γᵣ in the lateral direction.

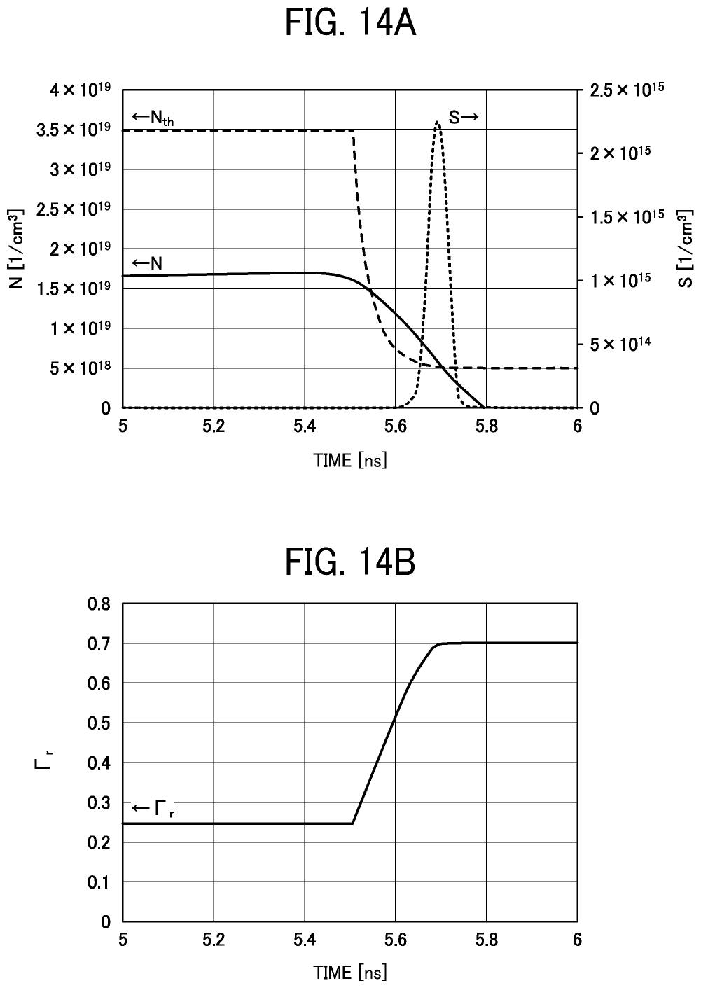

Since the optical confinement factor Γᵣ in the lateral direction is the function of the carrier density N, the optical confinement factor Γᵣ in the lateral direction decreases in a range from 3 ns to 5.5 ns in which the pulse current is injected. Within this range, the threshold carrier density Nₜₕ increases along with a decrease in the optical confinement factor Γᵣ in the lateral direction, and N<Nₜₕ is established. Hence induced emission is less likely to occur, and the photon density S does not increase. When the injection of the pulse current starts decreasing at the time point of about 5.5 ns, the optical confinement factor Γᵣ in the lateral direction increases again, and in the process, the photon density S appears in a pulse form. FIGS. 14A and 14B are graphs in which the time axis in the range from 5 ns to 6 ns in FIGS. 13A and 13B is expanded.

When the injection of the pulse current starts decreasing at the time point of about 5.5 ns, the carrier density N starts decreasing. At the same time, the optical confinement factor Γᵣ in the lateral direction increases, and the threshold carrier density Nₜₕ decreases. Since the decrease in the threshold carrier density Nₜₕ is faster than the decrease in the carrier density N, there is a period in which N>Nₜₕ is established in the process of the decrease in the carrier density N. During this period, the photon density S first increases due to spontaneous emission, and when the photon density S increases by a certain degree, induced emission becomes dominant, and the photon density S rapidly increases. At the same time, the carrier density N rapidly decreases, and when N<Nₜₕ is established again, the photon density rapidly decreases.

As described above, the phenomenon in which the optical pulse is output when the injection of the pulse current is stopped as a trigger can be reproduced by the simulation.

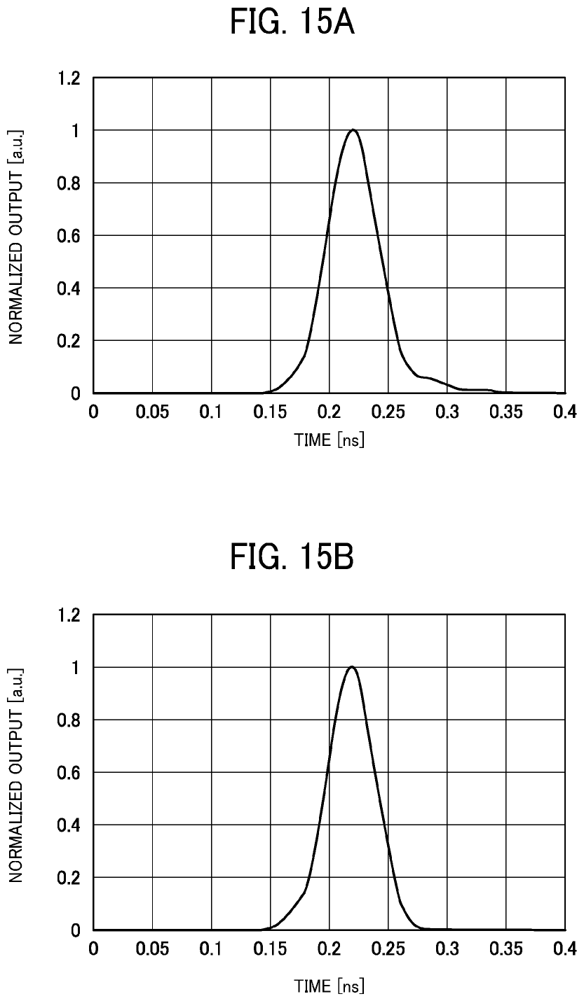

The rising time of the optical pulse decreases as the threshold carrier density Nₜₕ decreases faster than the carrier lifetime. That is, based on Equation (6), the rising time decreases as the increase in the lateral optical confinement factor Γᵣ is faster. The attenuation time of the optical pulse depends on the photon lifetime. FIGS. 15A and 15B are graphs presenting examples of an actual measurement result and a simulation result of optical pulses. FIG. 15A presents an actual measurement result. FIG. 15B presents a simulation result.

In the present specification, the optical pulse width is defined as a time width that is 1/e² of the peak value. The obtained optical pulse width is 86 ps in the actual measurement result in FIG. 15A, and is 81 ps in the simulation result in FIG. 15B. In this case, e is a natural logarithm. With this model, the width of the optical pulse is shorter than the pulse current to be injected, and can be decreased without being limited by the time width of the pulse current to be injected.

Table 1 presents the full width at half maximum (FWHM) and the optical pulse width (the time width of 1/e² of the peak value) in the actual measurement results in FIGS. 6A to 6C. In any case, FWHMs from 40 ps to 60 ps and optical pulse widths from 80 ps to 110 ps were obtained. The ratio of the optical pulse width to the full width at half maximum (optical pulse width/full width at half maximum) was from about 1.7 to about 1.8. Based on the definition of the Gaussian function formula, the ratio of the optical pulse width to the full width at half maximum is 1.70, and hence the optical pulse according to the present embodiment has a waveform close to the Gaussian function. In contrast, regarding the actual measurement results of the reference example (FIGS. 5A to 5C), since the constant tail light is output after the pulsed light, the optical pulse width is not 1/e² or less of the peak value until the current injection is stopped. That is, since the optical pulse width (the time width of 1/e² of the peak value) depends on the width of the pulse current, it is difficult to obtain an optical pulse width of the order of picoseconds.

TABLE 1

| | FIG. 6A | FIG. 6B | FIG. 6C |
|---|---|---|---|
| FWHM (ps) | 57.8 | 49.2 | 50.0 |
| 1/e² (ps) | 103.9 | 85.2 | 85.9 |
| Ratio | 1.80 | 1.73 | 1.72 |

In the present embodiment, a continuous optical pulse train is less likely to be generated after the optical pulse output is generated. This is because the injection of the pulse current decreases when the optical pulse is generated, and the relaxation oscillation is less likely to be generated.

Moreover, tail light is less likely to be generated after the optical pulse output is generated. This is because the injection of the pulse current decreases after the optical pulse is generated, and the carrier density is less likely to increase.

Furthermore, since the optical pulse is output immediately after the injection of the pulse current is stopped, the timing at which the optical pulse is output can be desirably controlled.

Furthermore, the width of the optical pulse generated according to the first embodiment is smaller than the width of the injected pulse current. Even when the current is increased, the pulse current width does not have to be decreased, and hence the pulse current width is less likely to be affected by parasitic inductance.

Multiple surface emitting lasers 100 according to the first embodiment may be arranged in parallel to form a surface emitting laser array, and optical pulses may be simultaneously output, thereby obtaining a larger optical peak output. The current injected into the surface emitting laser array is larger than the current injected into one surface emitting laser 100; however, since the width of the optical pulse output from the surface emitting laser 100 is smaller than the width of the injected pulse current, the optical pulse with a small width can be output.

The pulse width of the light output from the surface emitting laser 100 according to the first embodiment is not limited; however, the pulse width is, for example, 1 ns or less, preferably 500 ps or less, and more preferably 100 ps or less.

In the first embodiment, the thickness of the oxidized region 151 at a position 3 μm separated outward from the inner edge of the inner region 154, that is, at a position 3 μm separated outward from a tip end portion of the boundary between the non-oxidized region 152 and the oxidized region 151, is preferably twice or less the thickness of the non-oxidized region 152. For example, when the thickness of the non-oxidized region 152 is 31 nm, the thickness at the position 3 μm separated outward from the inner edge of the inner region 154 is preferably 62 nm or less, and may be 54 nm. When the distance (oxidation distance) from the side surface of the mesa 180 to the inner edge of the oxidized region 151 is in a range from 8 μm to 11 μm, the distance of 3 μm corresponds to 28% to 38% of the oxidation distance. When the thickness of the oxidized region 951 and the thickness of the non-oxidized region 952 were measured at the position 3 μm separated outward from the inner edge of the oxidized region 951 in actual measurement of the above-described reference example, the thickness of the oxidized region 951 was 79 nm, and the thickness of the non-oxidized region 952 was 31 nm. The thickness of the oxidized region 951 was 2.55 times the thickness of the non-oxidized region 952. As a result of comparative evaluation of various elements having oxidized confinement structures, the inventors have found that the optical confinement factor Γᵣ in the lateral direction decreases when the ratio is 2 or less, and short-pulse light with a high output and no tailing is likely to be obtained.

Described here are results of an optical mode simulation using actual measurement values of the first embodiment and the reference example. In the optical mode simulation, the refractive index of each region is set in a rotationally symmetrical multilayer structure model to calculate the electric field intensity distribution of the natural mode. Calculation was performed in the present optical mode simulation under a cold cavity condition not including the influence of heat generated by energization.

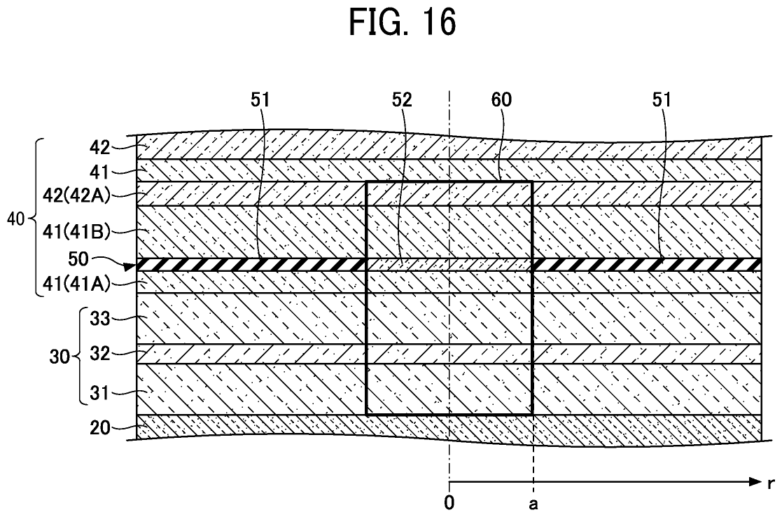

FIG. 16 is a cross-sectional view illustrating a first model used for a simulation. The first model includes an n-type DBR 20, an active layer region 30, and a p-type DBR 40. The active layer region 30 is on the n-type DBR 20, and the p-type DBR 40 is on the active layer region 30.

The active layer region 30 includes a lower spacer layer 31, a quantum well layer 32, and an upper spacer layer 33. The lower spacer layer 31 is on the n-type DBR 20, the quantum well layer 32 is on the lower spacer layer 31, and the upper spacer layer 33 is on the quantum well layer 32.

The p-type DBR 40 includes multiple low refractive index layers 41, multiple high refractive index layers 42, and an oxidized confinement layer 50. The lowermost low refractive index layer 41 (41A) is on the upper spacer layer 33. The oxidized confinement layer 50 is on the low refractive index layer 41A. The oxidized confinement layer 50 includes an oxidized region 51 and a non-oxidized region 52 in a plane perpendicular to the emission direction of light. The oxidized region 51 has an annular planar shape and surrounds the non-oxidized region 52. The non-oxidized region 52 is made of AlAs. The low refractive index layer 41 (41B) that is the second from the lower side is on the oxidized confinement layer 50. On the low refractive index layer 41B, high refractive index layers 42 and other low refractive index layers 41 are alternately stacked. In this model, the thickness of the oxidized region 51 is constant, and the oxidized region 51 does not have a tapered shape.

The optical thickness of the active layer region 30 is an oscillation wavelength λ. The sum of the thicknesses of the low refractive index layer 41A, the oxidized confinement layer 50, and the low refractive index layer 41B is 3λ/4. The thickness of the high refractive index layer 42A is λ/4.

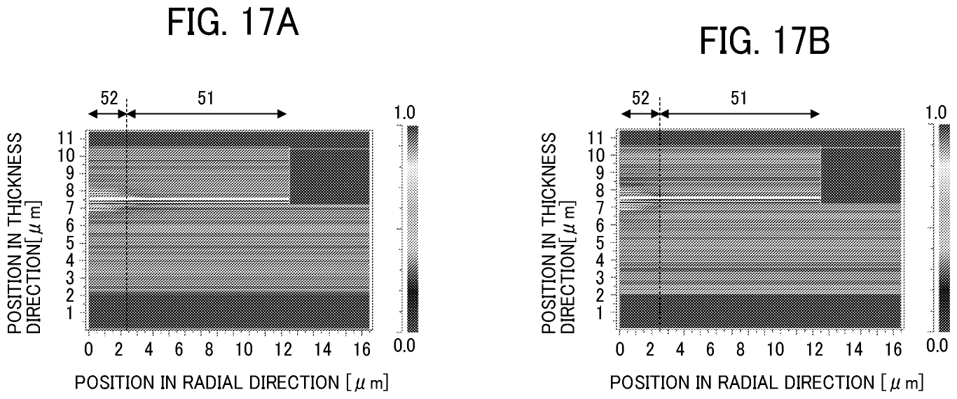

The relationship between the optical confinement factor and the thickness of the oxidized confinement layer 50 is described first. FIGS. 17A and 17B illustrate cross-sectional profiles of electric field intensity distributions of a fundamental mode in structures in which non-oxidized regions have a diameter of 5 μm. FIG. 17A illustrates a cross-sectional profile when the thickness of the oxidized confinement layer 50 is 20 nm. FIG. 17B illustrates a cross-sectional profile when the thickness of the oxidized confinement layer 50 is 40 nm. The optical confinement factor can be estimated as a ratio of the electric field intensity in the oxidized confinement layer 50 to the sum of the electric field intensities in the entire region. In the structure in which the thickness of the oxidized confinement layer 50 is 20 nm, the electric field intensity distribution expands in the lateral direction and the proportion of the electric field intensity distribution present outside the non-oxidized region 52 is large compared to the structure in which the thickness of the oxidized confinement layer 50 is 40 nm, and thus the optical confinement factor is small.

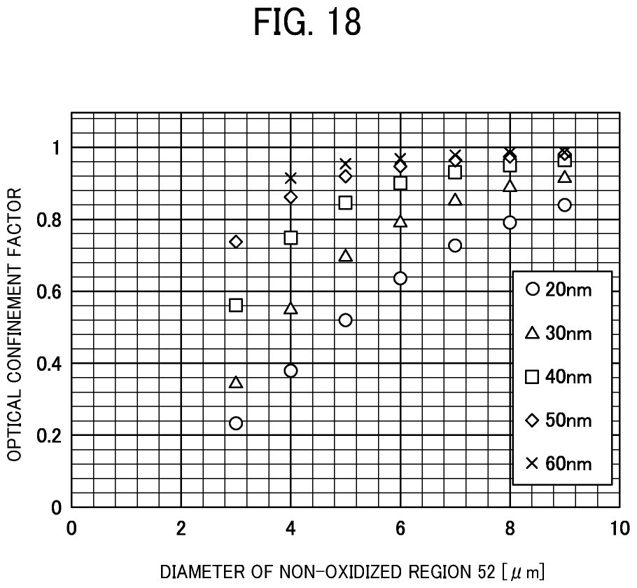

Described next is the relationship among the optical confinement factor, the thickness of the oxidized confinement layer 50, and the diameter of the non-oxidized region 52. FIG. 18 is a graph presenting calculation results of the relationship among the optical confinement factor, the thickness of an oxidized confinement layer, and the diameter of a non-oxidized region. The horizontal axis in FIG. 18 indicates the diameter of the non-oxidized region 52, and the vertical axis indicates the optical confinement factor. FIG. 18 presents the results of optical confinement factors calculated when the thickness of the oxidized confinement layer 50 is in a range from 20 nm to 60 nm and the diameter of the non-oxidized region 52 is in a range from 3 μm to 9 μm. In a range in which the thickness of the oxidized confinement layer 50 is 40 nm or more and the diameter of the non-oxidized region 52 is 5 μm or more, the optical confinement factor tends to be saturated to about 0.9 or more. This tendency corresponds to that the expansion of the electric field intensity distribution in the lateral direction increases as illustrated in FIG. 17A in a range in which the optical confinement factor is smaller than the saturation value, and the proportion of the electric field intensity outside the oxidized region is large.

The calculation results relating to the relationship among the thickness of the oxidized confinement layer 50, the diameter of the non-oxidized region 52, and the optical confinement factor have been described. Described next are the calculation results of an electric field intensity distribution when the refractive index near the tip end of the oxidized region 51 is intentionally decreased.

A region 60 whose refractive index is to be decreased was a region having a thickness of about 200 nm corresponding to the lowermost one pair of the p-type DBRs 40 above the non-oxidized region 52 (AlAs layer), and was a region having a thickness of about 300 nm including the upper spacer layer 33, the quantum well layer 32, and the lower spacer layer 31 below the non-oxidized region 52 (AlAs layer). The reason why the lower region is larger than the upper region is because the lower side is a direction close to the active layer region 30 and it is expected that the region with high carrier density is large. The region in the radial direction in which the refractive index was changed had the same range as the non-oxidized region 52.

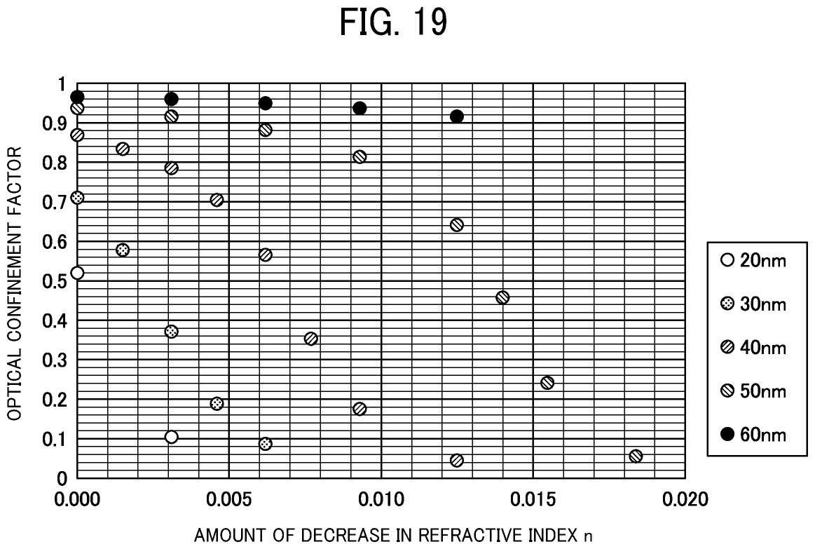

FIG. 19 is a graph presenting calculation results of the relationship between the thickness of an oxidized confinement layer and the optical confinement factor for the first model. The thicknesses of the oxidized confinement layer 50 included four levels in a range from 30 nm to 60 nm, and the amount by which the refractive index n was decreased (the amount by which the refractive index n was decreased) was in a range from 0 to about 0.02. In FIG. 19, the horizontal axis indicates the amount of decrease in the refractive index n, and the vertical axis indicates the optical confinement factor. The larger the amount by which the refractive index n is decreased, the lower the refractive index in the region 60. It is found that, in the case where the thickness of the oxidized confinement layer 50 is 60 nm, the optical confinement factor is hardly decreased even when the refractive index is markedly decreased; however, as the thickness of the oxidized confinement layer 50 is decreased, the optical confinement factor is likely to be decreased even when the amount of decrease in the refractive index n is small.

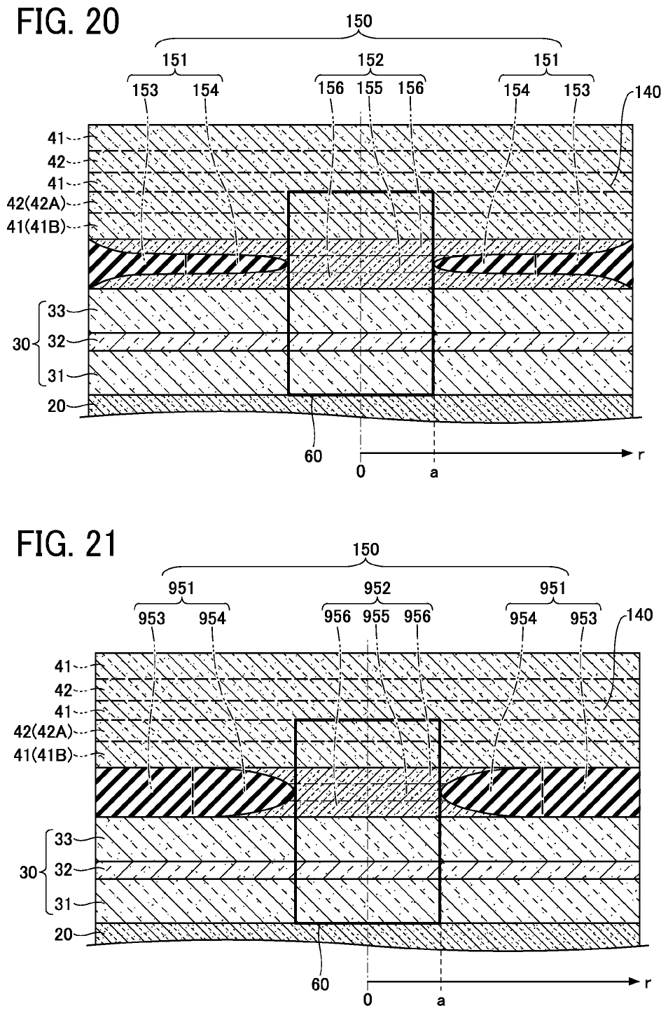

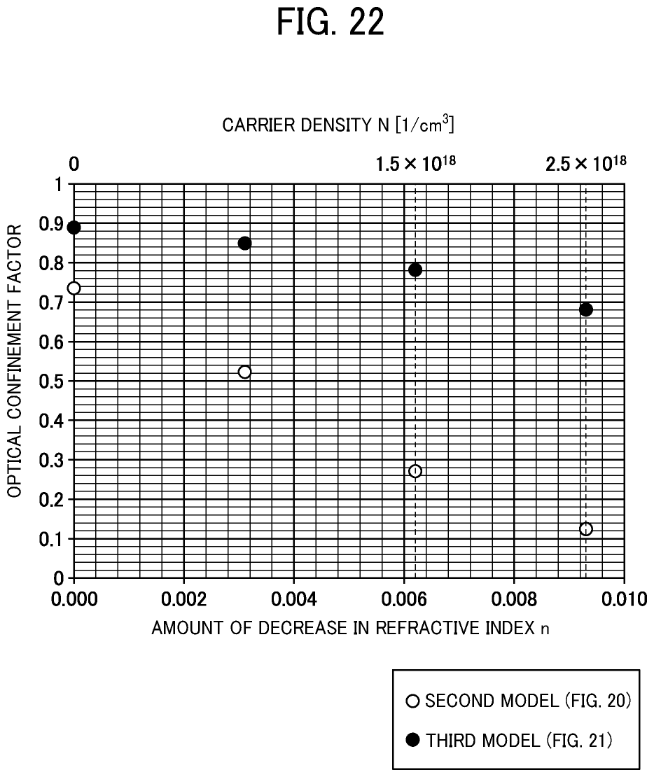

Results of simulations using a model closer to that of the first embodiment or the reference example are described next. FIG. 20 illustrates a second model used for the simulation. FIG. 21 illustrates a third model used for the simulation. The second model is a model closer to that of the first embodiment. The third model is a model closer to that of the reference example. The electric field intensity distribution when the refractive index near the tip end of the oxidized region was intentionally decreased was calculated for the second model and the third model, similarly to the first model.

FIG. 22 is a graph presenting calculation results of the relationship between the amount of decrease in refractive index and the optical confinement factor for the second model and the third model. The amount of decrease in the refractive index n was in a range from 0 to about 0.01. The horizontal axis on the lower side in FIG. 22 indicates the amount of decrease in the refractive index n, and the vertical axis indicates the optical confinement factor. As presented in FIG. 22, in the second model (FIG. 20) imitating the first embodiment, when the refractive index is decreased to about 0.01, the optical confinement factor, which was 0.7 before the refractive index was decreased, is decreased to 0.1. In contrast, in the third model (FIG. 21) imitating the reference example, when the refractive index is decreased to about 0.01, the optical confinement factor, which was 0.9 before the decrease, is decreased to 0.7. Thus, in the second model, the amount of change in optical confinement factor with respect to the decrease in the refractive index is large, and hence a pulsed-light output due to a rapid change in optical confinement factor can be provided.

As indicated by the upper horizontal axis in FIG. 22, when converted from Equation (2) for estimating the carrier plasma effect, an amount of decrease in the refractive index n being 0.006 corresponds to a carrier density N of 1.5×10¹⁸ [1/cm³], and an amount of decrease in the refractive index n being 0.010 corresponds to a carrier density N of 2.5×10¹⁸ [1/cm³]. FIG. 11 presents a function of decreasing the optical confinement factor in a range of the carrier density N from 5.0×10¹⁸ [1/cm³] to 1.5×10¹⁹ [1/cm³]. The range of the carrier density N differs between FIG. 11 and FIG. 22 because the carrier density in the quantum well layer is targeted in FIG. 11 whereas the target of changing the refractive index is a wide region including the upper and lower portions of the quantum well layer in FIG. 22. The carrier density in the wide region above and below the quantum well layer is expected to expand due to, for example, diffusion in the lateral direction. When it is assumed that the carrier density of the region with the decreased refractive index is smaller than the carrier density in the quantum well layer by about one digit, the range of the carrier density presented in FIG. 11 can be considered equivalent to the range of the carrier density presented in FIG. 22.

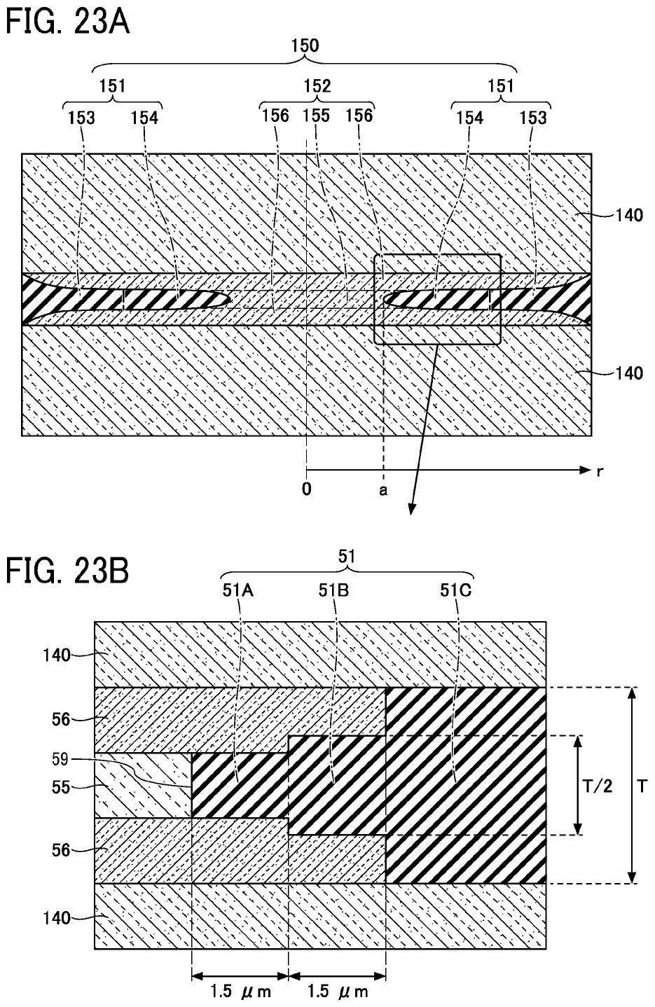

Described next are simulation results of the relationship between the thickness of the oxidized region at a position 3 μm from the boundary between the non-oxidized region 52 and the oxidized region 51 and the optical confinement factor according to the first embodiment. FIG. 23 provides cross-sectional views illustrating a fourth model used for the simulation. In the fourth model, the oxidized region 51 includes a first region 51A, a second region 51B, and a third region 51C. The planar shapes of the first region 51A, the second region 51B, and the third region 51C are annular. The first region 51A is located outside the non-oxidized region 52, the second region 51B is located outside the first region 51A, and the third region 51C is located outside the second region 51B. The non-oxidized region 52 includes an AlAs layer 55 and two AlGaAs layers 56 that sandwich the AlAs layer 55 in the vertical direction.

The thickness of the AlAs layer 55 is 30 nm. The thickness of the first region 51A is 30 μm, the thickness of the third region 51C is T [μm], and the thickness of the second region 51B is T/2 [μm]. The widths of the first region 51A and the second region 51B in the radial direction each are 1.5 μm. The thickness of the oxidized region 51 at a position 3 μm separated outward from the boundary between the non-oxidized region 52 and the oxidized region 51, that is, from a boundary 59 between AlAs layer 55 of the non-oxidized region 52 and the first region 51A, is the thickness of the third region 51C.

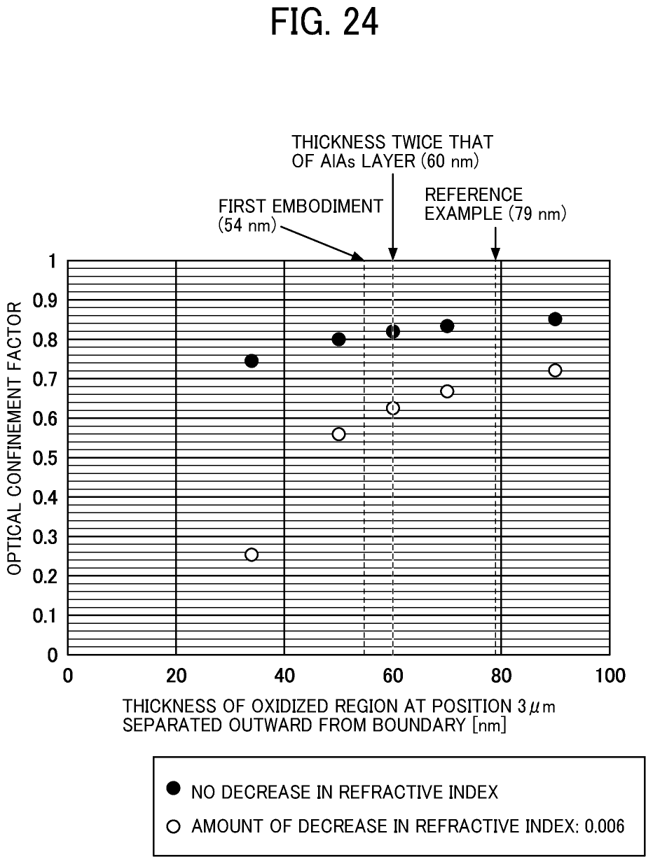

FIG. 24 is a graph presenting calculation results of the relationship between the thickness of an oxidized region at a position 3 μm separated outward from the boundary and the optical confinement factor for the fourth model. FIG. 24 presents calculation results when the refractive index does not decrease and calculation results when the refractive index decreases by 0.006. The horizontal axis in FIG. 24 indicates the thickness of the oxidized region 51 at the position 3 μm separated outward from the boundary 59, and the vertical axis indicates the optical confinement factor.

As presented in FIG. 24, it is found that when the thickness of the oxidized region 51 at the position 3 μm separated outward from the boundary 59 is 60 nm or less, the amount of decrease in optical confinement factor is large compared to a case where the thickness is more than 60 nm. That is, it is found that when the thickness of the oxidized region 51 at the position 3 μm separated outward from the boundary 59 is twice or less the thickness of the AlAs layer 55, the amount of decrease in optical confinement factor is large compared to a case where the thickness is more than twice the thickness of the AlAs layer 55. Thus, in the region in which the thickness of the oxidized region 51 at the position 3 μm separated outward from the boundary 59 is twice or less the thickness of the AlAs layer 55, the change in optical confinement factor with respect to the amount of change in refractive index is large, and hence the pulsed-light output due to a rapid change in optical confinement factor according to the first embodiment can be provided. The actual measurement value of the thickness of the oxidized region 151 at the position 3 μm separated outward from the inner edge of the inner region 154 of a sample fabricated according to the first embodiment was 54 nm. The actual measurement value of the thickness of the oxidized region 951 at the position 3 μm separated outward from the inner edge of the oxidized region 951 of a sample fabricated according to the reference example was 79 nm.

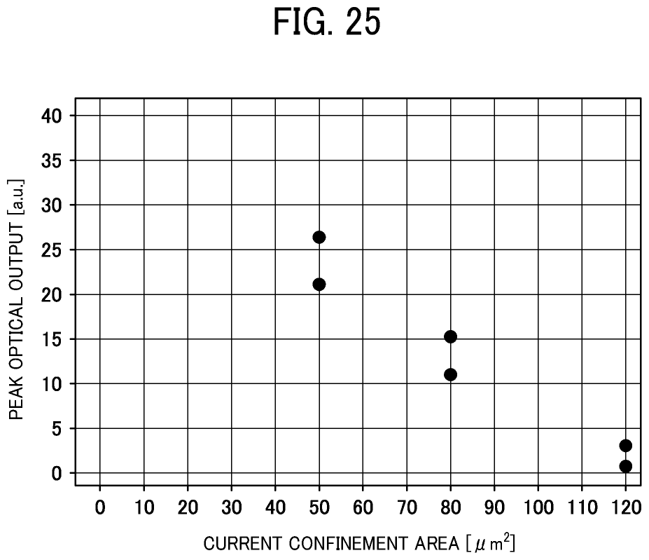

The area (current confinement area) of the non-oxidized region 152 in plan view is desirably 120 μm² or less. In other words, a region surrounded by the edge of a boundary between the low refractive index region and the high refractive index region in the plane perpendicular to the emission direction of light has an area of 120 μm² or less. As a result of comparative evaluation of various elements of the non-oxidized region 152, the inventors have found that the phenomenon in which the optical pulse is output immediately after the injection of the pulse current is stopped is less likely to occur when the non-oxidized region 152 has an area exceeding 120 μm². Moreover, it was found that an optical pulse with a high peak output is likely to be obtained as the non-oxidized region 152 is smaller. FIG. 25 is a graph presenting measurement results of a peak optical output for a sample in which the area of a non-oxidized region is in a range from 50 μm² to 120 μm².

### Second Embodiment

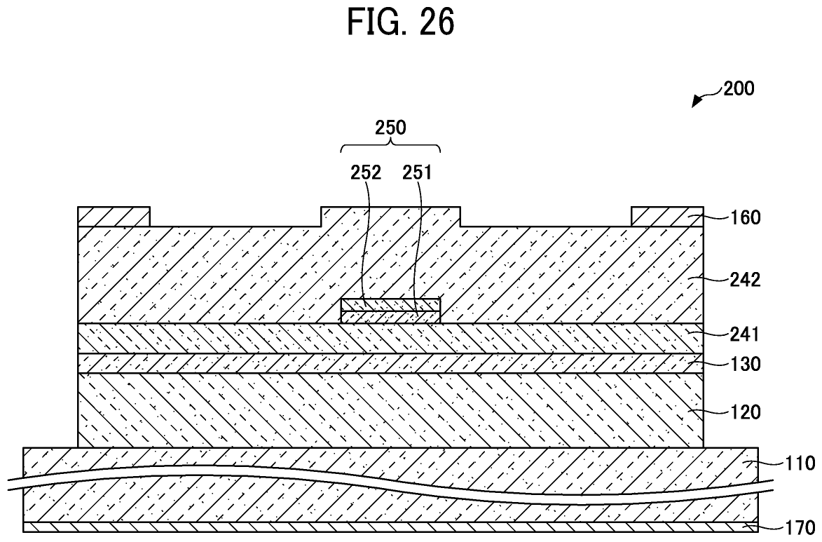

A second embodiment is described next. The second embodiment relates to a surface emitting laser. FIG. 26 is a cross-sectional view illustrating a surface emitting laser 200 according to the second embodiment.

The surface emitting laser 200 according to the second embodiment is, for example, a VCSEL including a current confinement structure by buried tunnel junction (BTJ). The surface emitting laser 200 includes an n-type GaAs substrate 110, an n-type DBR 120, an active layer 130, a p-type DBR 241, a BTJ region 250, a p-type DBR 242, an upper electrode 160, and a lower electrode 170.

The p-type DBR 241 is on the active layer 130. The p-type DBR 241 is, for example, a semiconductor multilayer-film reflecting mirror including multiple p-type semiconductor films stacked on one another. The BTJ region 250 is on a portion of the p-type DBR 241. The BTJ region 250 includes a p-type layer 251 and an n-type layer 252. The p-type DBR 242 is on the p-type DBR 241 and covers the BTJ region 250. The p-type DBR 242 is, for example, a semiconductor multilayer-film reflecting mirror including multiple p-type semiconductor films stacked on one another. The p-type DBR 242, the p-type DBR 241, the active layer 130, and the n-type DBR 120 include a mesa 280. The BTJ region 250 is located at the center of the mesa 280 in the plane.

The p-type layer 251 is on the p-type DBR 241. The n-type layer 252 is on the p-type layer 251. The p-type layer 251 contains a p-type impurity at a higher concentration than that of the p-type semiconductor film constituting the p-type DBR 241. The n-type layer 252 contains an n-type impurity at a higher concentration than that of the n-type semiconductor film constituting the n-type DBR 120. For example, the thickness of the p-type layer 251 is from 5 nm to 20 nm, and the thickness of the n-type layer 252 is from 5 nm to 20 nm. In plan view, a portion of the mesa 280 inside the contour of the BTJ region 250 is an example of a high refractive index region, and a portion of the mesa 280 outside the contour of the BTJ region 250 is an example of a low refractive index region.

The upper electrode 160 is in contact with an upper surface of the p-type DBR 242. The lower electrode 170 is in contact with a lower surface of the n-type GaAs substrate 110. The pair of the upper electrode 160 and the lower electrode 170 is an example of an electrode pair.

In the second embodiment, a reverse bias is applied and hence current does not flow between the p-type DBR 241 and the p-type DBR 242. Current flows between the p-type layer 251 and the n-type layer 252 by buried tunnel junction. Thus, the current path between the upper electrode 160 and the lower electrode 170 is confined at the center of the mesa 280 including the BTJ region 250. Moreover, since the BTJ region 250 forms a step and is covered with the p-type DBR 242, the refractive index in a plane of the mesa 280 is high at the center and is low in the periphery. Thus, an optical confinement effect in the lateral direction is generated in the surface emitting laser 200.

Thus, also according to the second embodiment, an optical pulse can be output by injecting pulse current similar to that in the first embodiment.

### Third Embodiment

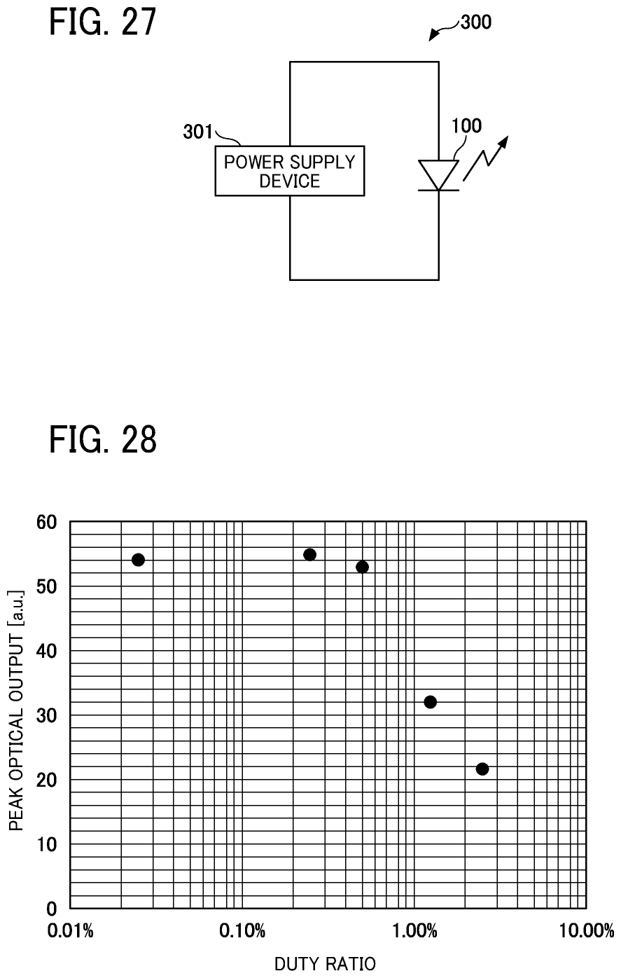

A third embodiment is described next. The third embodiment relates to a laser device. FIG. 27 is a diagram illustrating a laser device 300 according to the third embodiment.

The laser device 300 according to the third embodiment includes the surface emitting laser 100 according to the first embodiment, and a power supply device 301 coupled to the upper electrode 160 and the lower electrode 170 of the surface emitting laser 100. The power supply device 301 injects current to the surface emitting laser 100.

The duty ratio of the injection of current from the power supply device 301 is preferably 0.5% or less. That is, it is desirable that the current injection period and the current decrease period are repeated multiple times, and the ratio of the current injection period to the current decrease period is 0.5% or less. The duty ratio is a ratio of a period in which a current pulse is injected in a unit period. When t [s] denotes a pulse current width and f [Hz] denotes a repetition frequency of pulse current, the duty ratio corresponds to f×t (%). FIG. 28 is a graph presenting the relationship between the duty ratio and the peak output of optical pulses when the pulse current width is 2.5 ns.

As presented in FIG. 28, when the duty ratio is more than 0.5%, the optical peak output tends to decrease. Conceivable reasons for this are the following models. First, when the duty ratio is increased, the amount of heat generated in the current confinement region (non-oxidized region 152) by the injected pulse current increases. Thus, the temperature of the center portion where the current is concentrated rises with respect to the peripheral portion of the current confinement region, and a temperature difference is generated. Consequently, the refractive index of the center portion of the current confinement region increases by a thermal lens effect, and the optical confinement factor in the lateral direction increases. As the optical confinement factor in the lateral direction increases due to the thermal lens effect, the influence of a change in refractive index due to the carrier plasma effect generated by an increase or a decrease in pulse current decreases. Thus, the phenomenon in which the optical pulse is output immediately after the injection of the pulse current is stopped is less likely to occur. In contrast, when the duty ratio is 0.5% or less, the influence of the change in refractive index due to the thermal lens effect is sufficiently small, and the change in refractive index derived from the confinement structure is dominant, and thus the peak output is considered to be substantially constant and not changed.

In one example, instead of the surface emitting laser 100 according to the first embodiment, the surface emitting laser 200 according to the second embodiment may be used.

### Fourth Embodiment

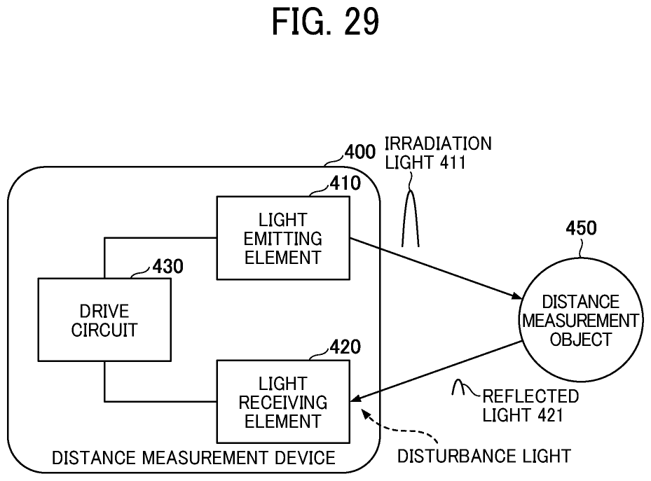

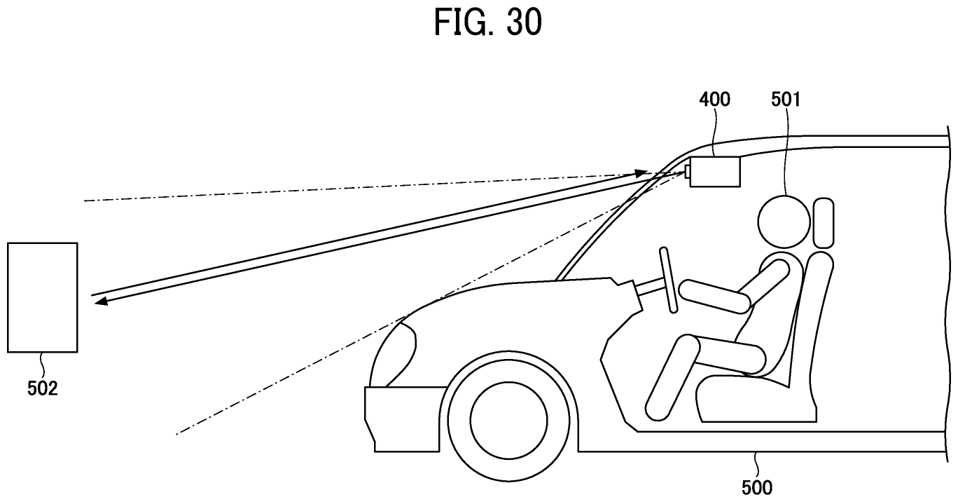

A fourth embodiment is described next. The fourth embodiment relates to a distance measurement device. FIG. 29 illustrates a distance measurement device 400 according to the fourth embodiment. The distance measurement device 400 is an example of a detection device.

The distance measurement device 400 according to the fourth embodiment is a distance measurement device based on a time of flight (TOF) method. The distance measurement device 400 includes a light emitting element 410, a light receiving element 420, and a drive circuit 430. The light emitting element 410 emits an emission beam (irradiation light 411) to a distance measurement object 450. The light receiving element 420 receives reflected light 421 from the distance measurement object 450. The drive circuit 430 drives the light emitting element 410 and detects the difference in time between the emission timing of the emission beam and the reception timing of the reflected light 421 by the light receiving element 420 to measure the distance of reciprocation to and from the distance measurement object 450.

The light emitting element 410 includes the surface emitting laser 100 according to the first embodiment or the surface emitting laser 200 according to the second embodiment. The light emitting element 410 may include multiple surface emitting lasers 100 according to the first embodiment or multiple surface emitting lasers 200 according to the second embodiment arranged in an array. The repetition frequency of pulses is, for example, in a range from several kilohertz to several tens of megahertz.

The light receiving element 420 is, for example, a photodiode (PD), an avalanche photodiode (APD), or a single photon avalanche diode (SPAD). The light receiving element 420 may include multiple light receiving elements arranged in an array. The light receiving element 420 is an example of a detector.

In the distance measurement by the TOF method, it is desirable to separate a signal from a distance measurement object and noise from each other. When a farther distance measurement object is measured or when a distance measurement object with a lower reflectivity is measured, it is desirable to obtain a signal from the object using a light receiving element with a higher sensitivity. However, when a light receiving element with a higher sensitivity is used, the possibility of erroneously detecting background light noise or shot noise increases. To separate the signal and the noise from each other, the threshold value of the light receiving signal may be increased; however, it may be difficult to receive the signal light from the distance measurement object unless the peak output of the emission beam is increased by the amount by which the threshold value of the light receiving signal is increased. However, the output of the emission beam is limited by the safety standards for lasers.

The surface emitting laser 100 according to the first embodiment or the surface emitting laser 200 according to the second embodiment can output optical pulses having a pulse width of about 100 ps. This is about 1/10 compared to the value ns of the optical pulse width output from the surface emitting laser of the related art. According to the fourth embodiment, since the peak output allowable under the safety standard increases as the pulse width of the optical pulse decreases, both an increase in precision and an increase in distance can be attained while eye-safe is satisfied.

### Fifth Embodiment

A fifth embodiment is described next. The fifth embodiment relates to a mobile object. FIG. 30 illustrates an automobile 500 as an example of a mobile object according to the fifth embodiment. The distance measurement device 400 described in the fourth embodiment is provided at an upper portion of a front surface of the automobile 500 (for example, an upper portion of a windshield) as an example of a mobile object according to the fifth embodiment. The distance measurement device 400 measures the distance to an object 502 around the automobile 500. The measurement result of the distance measurement device 400 is input to a controller included in the automobile 500, and the controller controls the operation of the mobile object based on the measurement result. Alternatively, the controller may provide warning indication on a display provided in the automobile 500 to a driver 501 of the automobile 500 based on the measurement result of the distance measurement device 400.

As described above, in the fifth embodiment, since the distance measurement device 400 is provided in the automobile 500, the position of the object 502 in the periphery of the automobile 500 can be recognized with high precision. The installation position of the distance measurement device 400 is not limited to the upper and front portion of the automobile 500, and may be installed at a side surface or a rear portion of the automobile 500. In this embodiment, the distance measurement device 400 is provided in the automobile 500; however, the distance measurement device 400 may be provided in an aircraft or a ship. In one example, the distance measurement device 400 may be provided in a mobile object that moves autonomously without a driver, such as a drone or a robot.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

Any one of the above-described operations may be performed in various other ways, for example, in an order different from the one described above.

This patent application is based on and claims priority to 35 U.S.C. § 119(a) to Japanese Patent Application No. 2021-126011, filed on Jul. 30, 2021, Japanese Patent Application No. 2022-010790, filed on Jan. 27, 2022, and Japanese Patent Application No. 2022-024125, filed on Feb. 18, 2022, in the Japan Patent Office, the entire disclosure of which is hereby incorporated by reference herein.

### REFERENCE SIGNS LIST

100, 200 Surface emitting laser
120 N-type DBR
130 Active layer
140, 241, 242 P-type DBR
150 Oxidized confinement layer
151 Oxidized region
152 Non-oxidized region
160 Upper electrode
170 Lower electrode
180, 280 Mesa
250 BTJ region
251 P-type layer
252 N-type layer
300 Laser device
400 Distance measurement device
500 Automobile (mobile object)

1: A surface emitting laser comprising:
an active layer;
multiple reflectors facing each other with the active layer therebetween; and
an electrode pair coupled to a power supply and to inject current into the active layer,
wherein the surface emitting laser has:
a current injection period in which the current is injected by the power supply to oscillate no laser beam; and
a current decrease period after the current injection period, in which a current value of the current injected into the active layer is lower than a current value of the current injected during the current injection period, to oscillate a laser beam.

2: The surface emitting laser according to claim 1, further comprising, in a plane perpendicular to an emission direction of light:
a first refractive index region; and
a second refractive index region surrounding the first refractive index region and having a refractive index lower than the refractive index of the first refractive index region.

3: The surface emitting laser according to claim 2,
wherein the second refractive index region is formed by oxidation confinement,
wherein the first refractive index region has a thickness of 35 nm or less, and
wherein the second refractive index region has a thickness twice or less the thickness of the first refractive index region at a position of 3 μm from a tip end portion of a boundary between the second refractive index region and the first refractive index region.

4: The surface emitting laser according to claim 2, wherein a region surrounded by an edge of a boundary between the second refractive index region and the first refractive index region in the plane perpendicular to the emission direction of light has an area of 120 μm2 or less.

5: The surface emitting laser according to claim 2, wherein the first refractive index region and the second refractive index region are formed by buried tunnel junction.

6: The surface emitting laser according to claim 1, wherein the surface emitting laser outputs an optical pulse having a time width shorter than the current injection period.

7: A surface emitting laser configured to, when a time width of 1/e2 of a peak value is defined as an optical pulse width, emit a single optical pulse having an optical pulse width of 110 ps or less.

8: A laser device comprising:
the surface emitting laser according to claim 1; and
a power supply coupled to the electrode pair and to inject current into the surface emitting laser.

9: The laser device according to claim 8,
wherein the current injection period and the current decrease period are repeated multiple times, and
wherein a ratio of the current injection period to the current decrease period is 0.5% or less.

10: A laser device comprising the surface emitting laser according to claim 7.

11: A detection device comprising:
the laser device according to claim 8; and
a detector to detect light emitted from the surface emitting laser and reflected by an object.

12: The detection device according to claim 11, wherein the detection device calculates a distance to the object based on a signal from the detector.

13: A mobile object comprising the detection device according to claim 12.

14: A surface emitting laser driving method performed by a surface emitting laser including an active layer, multiple reflectors facing each other with the active layer therebetween, and an electrode pair and to inject current into the active layer, the method comprising:
oscillating no laser beam during a current injection period in which the current is injected by a power supply; and
oscillating a laser beam during a current decrease period after the current injection period, in which a current value of the current injected into the active layer is lower than a current value of the current injected during the current injection period.
